(19) United States
(12) Patent Application Publication
(10) Pub. No.: US 2025/0157987 A1
(43) Pub. Date: May 15, 2025

(54) HYBRID BONDED INVERTED MEMORY-LOGIC STACK

(71) Applicant: Advanced Micro Devices, Inc., Santa Clara, CA (US)

(72) Inventor: Gabriel LOH, Bellevue, WA (US)

(21) Appl. No.: 18/509,410

(22) Filed: Nov. 15, 2023

(51) Int. Cl. H01L 25/065; H01L 23/00; H01L 23/367; H01L 23/48; H01L 23/498; H01L 25/18

(52) U.S. Cl. CPC H01L 25/0657; H01L 23/367; H01L 23/481; H01L 23/49827; H01L 24/16; H01L 25/18; H01L 2224/16145; H01L 2225/06541; H01L 2924/1434

(57) ABSTRACT

Memory layers and a digital device layer are configured into a three-dimensional integrated circuit (IC) die stack. The digital device layer has a first surface (side) located closest to a cooling solution and the memory layers are located on a second surface (side) of the digital device layer opposite to the first surface (side) thereof. The cooling solution is adapted to receive and dissipate heat from the digital device layer and the memory layers. Through-silicon vias (TSV) running through the memory layers and to the digital device layer are used to interconnect the signal, control and power supply voltages to circuits in these layers. Some of the TSVs are used to couple to external connections of a memory stack device. The digital device layer may be a complex electronic device layer such as a microprocessor or microcontroller for improved high speed signal transfers.

### TECHNICAL FIELD

Embodiments of the present disclosure generally relate to integrated circuit packaging of memory and logic dice, and in particular, to configurations of memory and logic dice arranged in a stack for use in integrated circuit packages that have improvements in thermal management thereof.

### BACKGROUND

Memory and logic (e.g., processors and peripheral) dice, stacked and interconnected vertically, are gaining interest among memory and processor suppliers and users to further increase memory bandwidth, reduce memory latency, reduce data movement power and increase component integration density. Current literature/prior art focuses on package topologies that stack the memory dice on top of logic die(s), which can lead to significant thermal challenges as the memory dice act as a major thermal insulator between the generally hotter logic (processor) die(s) and a cooling solution, e.g., heat sink, trapping the processor's heat which leads to higher die temperatures, lower performance, and degraded reliability. Consideration and use of micro-bump-based memory die interconnections has inferior thermal/electrical conduction properties since the micro-bump spacing between dice and fill material there between further degrades thermal conductivity of the dice stack.

Memory, e.g., dynamic random-access memory (DRAM), comprising stacked semiconductor dice, e.g., high bandwidth memory (HBM), in integrated circuit packages, face thermal challenges due to a potentially large number of layers of stacked semiconductor dice that present increasing thermal resistance for heat dissipation from the bottom of the dice stack to the cooling solution at the top of the dice stack. Typically, the majority of the power generation/consumption of a memory die stack comes from the bottom layer that may contain at least one digital processor comprising computing logic, physical electronics (PHY layer) for serializer/de-serializer (SerDes), address, read, write and refresh logic, data and address input receivers and output drivers, and DC voltage regulators for interfacing to the memory and external circuits. The processor computing logic and PHY layer consist of much of the higher-activity/higher-power circuitry, which located at the bottom of the dice stack in the integrated circuit package, is furthest from a cooling solution (e.g., air cooled heat sink with fins, liquid cooling pipes), generally, at the top of the integrated circuit package. Therefore, the heat generated from the processor computing logic and PHY layer die(s) has to travel through the memory layer dice.

Excess heat in the memory circuitry may cause degradation in performance and require more frequent and higher refresh power to maintain the memory data contents stored therein. Currently, the main solutions dealing with high memory temperatures are to either throttle down in speed the memory/computer system in some way to reduce power consumption enough to reduce the amount of excess heat, and/or use of more expensive/exotic cooling solutions (e.g., liquid cooling, cold plate, immersion cooling), neither/both of which are undesirable. Another solution to ensure reliable operability of DRAM at higher temperatures is to increase the refresh rate which eventually leads to lower performance/fewer instructions per cycle (IPC) and increased power overhead.

### SUMMARY

In one example of the disclosure, an IC die stack includes a digital device layer having a memory interface. A cooling solution on a first side of the digital device layer. And a plurality of memory layers on a second side of the digital device layer opposite the first side thereof.

In one example of the disclosure, an IC die stack includes a first digital device layer having at least two memory interfaces. A cooling solution on a first side of the first digital device layer. At least two memory stacks, each comprising a plurality of memory layers on a second side of the first digital device layer opposite the first side thereof. An interface layer between the first digital device layer and the at least two memory stacks. And a package substrate coupled to the at least two memory stacks on the opposite side of the at least two memory stacks coupled to the first digital device layer.

In one example of the disclosure, an IC die stack includes a plurality of compute modules, wherein at least one of the plurality of compute modules has a memory interface. A cooling solution on a first side of the plurality of compute modules, At least two memory stacks, each comprising a plurality of memory layers on a second side of the plurality of compute modules opposite the first side thereof, Interposer layers between the plurality of compute modules and the at least two memory stacks. A bridge electrically intercoupling the interposer layers. And a package substrate coupled to the at least two memory stacks on the opposite side of the at least two memory stacks coupled to the first digital device layer.

### BRIEF DESCRIPTION OF THE DRAWINGS

So that the manner in which the above recited features of the present invention can be understood in detail, a more particular description of the invention, briefly summarized above, may be had by reference to examples, some of which are illustrated in the appended drawings. It is to be noted, however, that the appended drawings illustrate only typical examples of this invention and are therefore not to be considered limiting of its scope, for the invention may admit to other equally effective examples.

FIG. 1 illustrates a representative schematic elevational cross-section layout of a prior art memory, peripheral logic and microprocessor stack.

FIG. 2 illustrates representative schematic elevational cross-section layouts of other prior art memory and processor stacks.

FIG. 3 illustrates a representative schematic elevational cross-section layout of a three-dimensional digital device/memory stack having a digital device layer interposed between a cooling solution and a plurality of memory layers, according to an example.

FIG. 4 illustrates a representative schematic elevational cross-section layout of a three-dimensional digital device/memory stack showing power, ground and signal connections between a digital device layer and a package substrate with a plurality of memory layers there between, according to an example.

FIG. 5 illustrates a representative schematic elevational cross-section layout of a three-dimensional digital device/memory stack showing through-mold/through-dielectric vias (TDVs) directly between the digital device and the package substrate, according to an example.

FIGS. 6 and 7 illustrate representative schematic elevational cross-section layouts of three-dimensional memory stacks having at least one non-memory silicon die alongside the memory stack that provides connectivity directly between the digital device and the package substrate, according to examples.

FIG. 8 illustrates a representative schematic elevational cross-section layout of a three-dimensional digital device/memory stack showing a plurality of compute modules and an active interposer layer between a cooling solution and a plurality of memory layers, according to an example.

FIG. 9 illustrates a representative schematic elevational cross-section layout of a three-dimensional digital device/memory stack having a digital device layer interposed between a cooling solution and multiple stacks of pluralities of memory layers, according to an example.

FIGS. 10 and 11 illustrate representative schematic elevational cross-section layouts of three-dimensional digital device/memory stacks using different types of electrical bonding technologies, according to examples.

FIGS. 12 and 13 illustrate representative schematic elevational cross-section layouts of three-dimensional digital device/memory stacks having at least two digital device modules connected through various silicon bridge technologies to at least two memory stacks.

To facilitate understanding, identical reference numerals have been used, where possible, to designate identical elements that are common to the figures, and a lower-case letter added where the elements are substantially the same. It is contemplated that elements of one embodiment may be beneficially incorporated in other embodiments.

### DETAILED DESCRIPTION

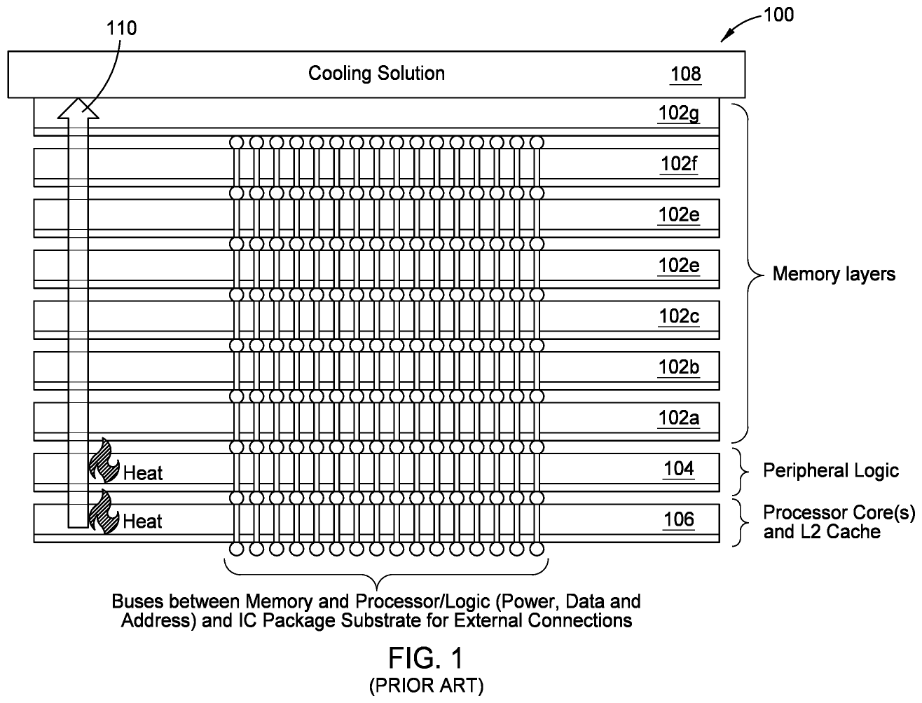

Referring to FIG. 1, depicted is a representative schematic elevational cross-section layout of a prior art memory, peripheral logic and microprocessor stack. A three-dimensional memory, e.g., dynamic random-access memory (DRAM), peripheral logic and microprocessor stack, generally represented by the numeral 100, comprises a plurality of integrated circuit (IC) semiconductor wafers: DRAM layers 102, peripheral logic layer 104, and processor core layer 106 vertically stacked, one above another with the processor core layer 106 at the bottom of the stack of DRAM layers 102. A cooling solution 108, e.g., heat sink with fins, liquid cooling tubes, etc., may be implemented at the top of the DRAM, peripheral logic and microprocessor stack 100, and receive and dissipate heat from the DRAM layers 102, peripheral logic layer 104 and processor core layer 106. FIG. 1 depicts an example three-dimensional DRAM, peripheral logic and microprocessor stack 100, e.g., system on a chip (SoC), typical of present technology implementations for high capacity and speed memory, e.g., high bandwidth memory (HBM). The peripheral logic layer 104 toward the bottom may consist of circuits to the DRAM layers 102 and the processor core layer 106. The processor core layer 106 at the bottom may be electrically coupled to the peripheral logic layer 104, DRAM layers 102, and external IC package connections, e.g., primarily power delivery and memory interface signals (address, command, and data signals) to the DRAM layers 102 and peripheral logic layer 104, and may also include other circuits and connections for debug, test, control, etc., of the DRAM layers 102, peripheral logic layer 104 and processor core layer 106.

The peripheral logic layer 104 and processor core layer 106 have been located closest to the substrate of the SoC integrated circuit package external connections, typically, because the peripheral logic layer 104 and processor core layer 106 have many electrical connections, e.g., for power, ground and data/address input/output (I/O), which are easier to escape from the peripheral logic layer 104 and processor core layer 106 (dice) to the IC package substrate when the peripheral digital device core dice are at the bottom of the stack 100, as shown in FIG. 1. However, this causes thermal conduction challenges as heat from the peripheral logic layer 104 and processor core layer 106 face increased thermal resistance because of the memory layers 102 being located between the peripheral logic layer 104/processor core layer 106, and the cooling solution 108.

Memory and peripheral logic interfaces, in particular, of the processor core layer 106 typically operate at very high speeds to achieve high data rate capacity transfer performance. Memory interface circuits operating at high data transfer rates, can consume a significant amount of power. The power consumption of the stack 100 generates heat (fire icon 110), which must then make its way up through the rest of the stack 100 (memory layers 102) to the cooling solution 108 where the heat can be removed. In a high bandwidth memory (HBM)-processor stack, for example, roughly 40 percent or more of the total power can be dissipated within the processor core layer 106. With an increasingly tall stack of DRAM layers 102 (e.g., eventually 12-16 high), can lead to a sharp increase in temperature of the processor core layer 106 and peripheral logic layer 104 due to the distance and insulating properties of the DRAM layers 102 between the processor core layer 106 and peripheral logic layer 104, and the cooling solution 108. For DRAM circuits especially, this elevated temperature can impact performance (due to the need for more frequent refreshes), power consumption (again due to the need for more frequent refreshes) and reliability.

Some three-dimensional (3D) integrated circuit (IC) stacking configurations having the processor between the memory layers and the cooling solution have been designed and evaluated. In one design/study: Dae Hyun Kim et al., “3D-MAPS: 3D Massively Parallel Processor with Stacked Memory”, in ISSCC 2012, an academic prototyping design located the processor between a memory and a cooling solution. This design has several challenges/flaws that make it impractical for serious industrial/commercial use. For example, all power (and I/O) conductors are routed around the outside/perimeter of the entire logic/memory stack, and then delivered to the side of the logic die opposite the side at the memory. Modern high-power integrated circuit dice cannot reliably receive all of their power/current from just the die periphery without suffering crippling voltage (IR) drops. Furthermore, routing power and ground conductors to the top of the logic die at the top of the stack, necessarily separates the top silicon layer (digital device die) from the cooling solution. This inhibits heat transfer from the digital device die to the cooling solution because a molding compound (thermal insulator) must be used to separate the top of the digital device die from the thermal interface material (TIM) and heat sink (cooling solution).

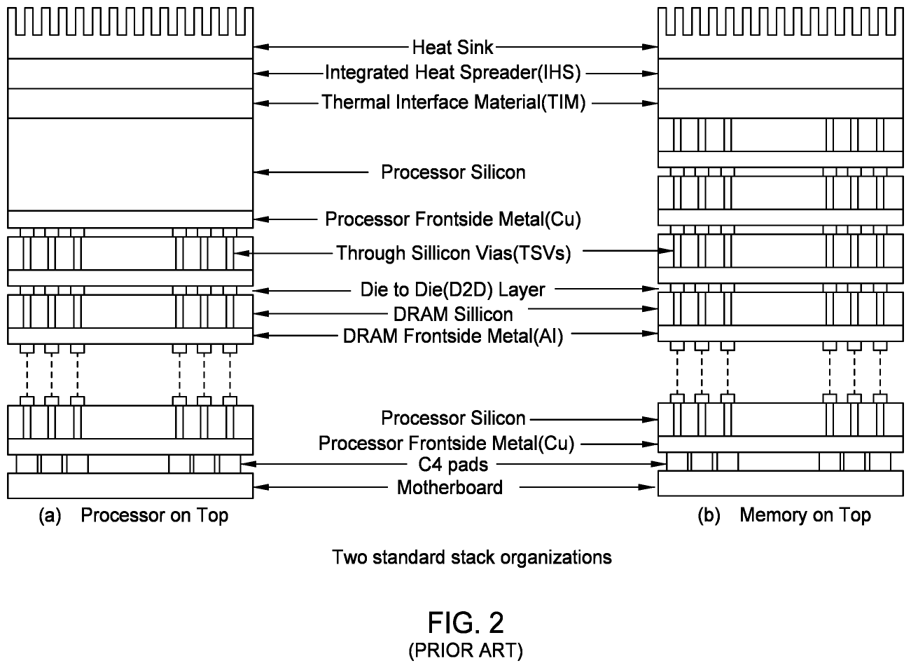

In another prior art technical paper, 3D-stacking of microbump-connected memory underneath a processor die was considered. Agarwal et al., “Xylem: Enhancing Vertical Thermal Conduction in 3D Processor-Memory Stacks,” in MICRO 2017. Referring to FIG. 2, depicted are representative schematic elevational cross-section layouts of other prior art memory and processor stacks. In FIG. 2(a) the processor is placed above the memory (DRAM), and power and ground are coupled to the processor with through silicon vias (TSV) and microbumps that result in significant voltage (IR) drop from the motherboard to the processor. This is why present technology 3D memory/processor stacks have the processor placed closest to the printed circuit motherboard having high current lands thereon, as shown in FIG. 2(b). But when the processor is placed closest to the printed circuit motherboard, a plurality of die-to-die (D2D) layers between the silicon wafers and surrounding the microbumps add significant thermal resistance between the processor and the cooling solution (heat sink).

According to the teachings of this disclosure, a digital device layer(s) and a plurality of memory layers, e.g., dynamic random-access memory (DRAM), static random-access memory (SRAM), serial shift registers, eDRAM, Flash, phase-change memory, resistive RAM, ferromagnetic RAM, spin-torque transfer RAM and the like may be configured in a three-dimensional memory stack. This digital device/memory stack may have the logic/process layer(s) and the plurality of memory layers inverted from the construction of the memory stack of the prior art. The inverted memory stack has a first surface (side) of the logic/process layer(s) located closest to the cooling solution and the plurality of memory layers located on a second surface (side) of the memory interface layer opposite to the first surface (side) thereof. This inverted digital device/memory stack configuration substantially alleviates and/or mitigates the thermal challenges of efficiently removing heat from the memory interface layer since now it is closest to the cooling solution and not being thermally insulated by the memory layers.

Placing the higher heat generating digital device layer(s) closer to the cooling solution, improves the efficiency of heat transfer therefrom. Placing the memory layers between the digital device layer(s) and the substrate, for coupling to a printed circuit board, necessitates having enough current carrying capacity electrical power conductors from the substrate, through the memory layers and to the digital device layer with sufficiently low voltage drop. This may be achieved by eliminating microbumps in the power delivery paths and replacing them with significantly lower resistance metal bonding pads, e.g., hybrid-bonding, copper hybrid-bonding. This solves the significant voltage drop problem associated with using microbumps for electrical power circuit connections. An added benefit is elimination of the die-to-die (D2D) layers between the silicon wafers, allowing direct metal-to-metal electrical connections (hybrid-bonding) between die layers, further reducing the resistance of connections there between. Another added benefit is elimination of power, ground and signal TSVs through the digital device die(s). Thus, removing the need to perforate the (expensive) digital device die(s) with TSVs is a significantly beneficial factor in digital device die manufacturing, that would otherwise be required if the digital device logic was located between the substrate and memory layers. TSVs may not be supported in some present and future leading-edge silicon digital device designs. Also, memory dice have freer die area available for TSV pass-through than a complex digital device die.

Various features are described hereinafter with reference to the drawing figures. It should be noted that the drawing figures may or may not be drawn to scale and that the elements of similar structures or functions are represented by like reference numerals throughout the drawing figures. It should be noted that the drawing figures are only intended to facilitate the description of the features of the examples. They are not intended as an exhaustive description of the examples below or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described. Referring now to the drawing figures, the details of examples are representative layouts schematically illustrated. Like elements in the drawing figures will be represented by like numbers, and similar elements will be represented by like numbers with a different lower-case letter suffix.

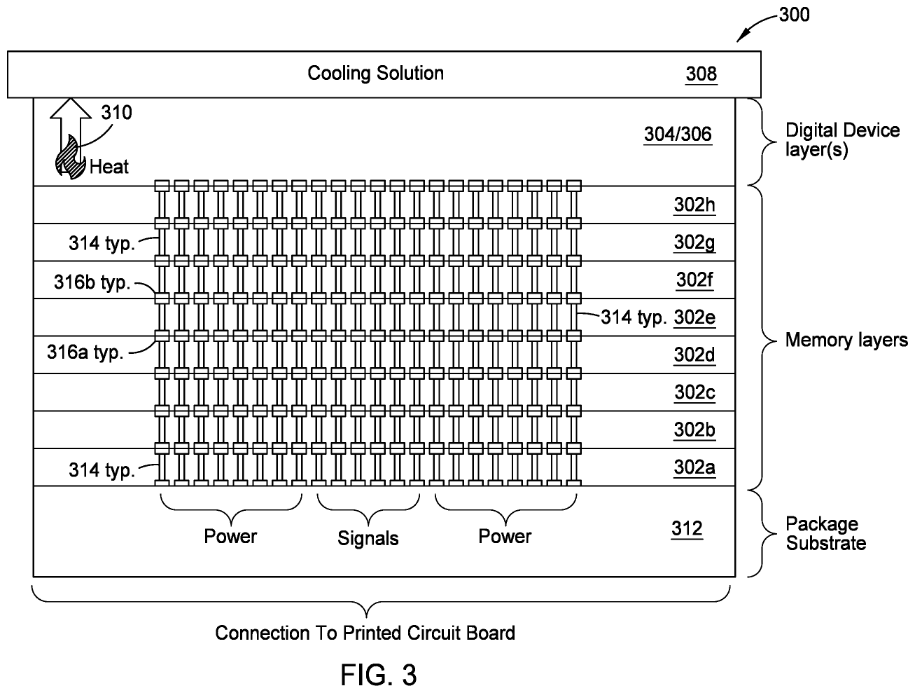

Referring to FIG. 3, depicted is a representative schematic elevational cross-section layout of a three-dimensional digital device/memory stack having a digital device layer interposed between a cooling solution and a plurality of memory layers, according to an example. A three-dimensional digital device/memory stack, generally represented by the numeral 300, comprises a digital device layer(s) 304, and a plurality of integrated circuit (IC) semiconductor memory (die) layers 302 vertically stacked one below another with the digital device layer(s) 304 closest to a cooling solution 308. The cooling solution 308 may be a thermal dissipation device with heat transfer enhancement structures such as, for example but not limited to, a heat sink, a heat sink with fins, liquid cooling tubes, vapor chambers, heat pipes, cold plates and the like.

The cooling solution 308 is adapted to receive and dissipate heat from the digital device layer(s) 304 and the plurality of memory layers 302. The digital device layer(s) 304, proximate to the cooling solution 308, may comprise interface circuits to external IC package connections, e.g., memory interface signals (address, command, and data) to the memory layers 302 and/or digital device layer(s) 304, and may also include other circuits and connections for debug, test, control, etc., of the plurality of memory layers 302. Power delivery to the plurality of memory layers 302 and digital device layer(s) 304 may be provided directly from the bottom of the stack 300, e.g., via a package substrate 312 (part of an integrated circuit package) having electrical connections, e.g., ball grid array, adapted for coupling to a printed circuit.

The higher-power dissipation circuitry (digital device layer(s) 304) may be placed proximate to the cooling solution 308 in the digital device/memory stack 300, instead of having the plurality of memory layers 302 there between. This significantly reduces the thermal resistance between the circuitry in the digital device layer(s) 304 and the cooling solution 308, thereby enabling the plurality of memory layers 302 to maintain lower operating temperatures. The majority of heat is generated by the digital device layer(s) 304 and has a much shorter distance to travel to the cooling solution 308, as represented by the fire arrow 310. The digital device die(s) (layer(s)) 304 typically is/are not thinned (or not thinned nearly as much as the other memory layers 302) since it does not need to provide for integration of through-silicon vias (TSV). This in turn improves spreading of heat laterally by reducing thermal resistance which is also a key attribute for reducing the severity of localized semiconductor die hotspots. There are a few considerations for this organization. First, the connections from the external signal paths (address/command/data) have to be routed to the digital device layer(s) 304 through the plurality of memory layers 302, which may require more TSVs, for power and ground that in turn increases the die area required by the TSVs for each of the plurality of memory layers 302.

Through silicon vias (TSVs) 314 passing through the plurality of memory layers 302 may be used to electrically connect the digital device layer(s) 304 to the package substrate 312. A plurality of TSVs 314 can be utilized for providing power and ground conductors to ensure sufficient power delivery (minimize voltage drop) to the digital device layer(s) 304. The TSVs 314 may be distributed across various locations in the plurality of memory layers 302 for providing enough current carrying capacity to different regions of the digital device layer(s) 304. Depending on the layout of the stacked memory layers 302, the TSVs 314 may not significantly increase area overhead if they can be placed in whitespace/unutilized regions of the plurality of memory layers 302. Otherwise, additional silicon area in the memory layers 302 may be allocated to accommodate the additional TSVs 314 for power and ground. For example, for TSVs 314 placed at a pitch of 9 um, each capable of carrying 10 mA of current (slightly conservative compared to current designs), 10,000 TSVs (at 10 mA each) for voltage plus 10,000 TSVs for the return current (ground), to support 100 watts of power at one (1) volt at 100 amperes, would require an area of about 1.62 mm². Given that a 3D memory stack, like high bandwidth memory (HBM), has an area greater than 100 mm², 1.62 mm² is an area overhead of only about 1.62 percent or less. Additional TSVs 314 may likewise be allocated for input-output (I/O) signals connecting the digital device layer(s) 304 through the plurality of memory layers 302 to the package substrate 312. Flush conductive pads 316 may be used to electrically connect the TSVs 314, using, for example but not limited to, hybrid-bonding, copper hybrid-bonding. Faces of the connection pads 316 are polished to be substantially flush with the surfaces of the silicone dice. Then the connection pads 316 of the semiconductor dice are electrically connected using hybrid-bonding. Using incremental area overhead of the plurality of memory layers 302 are preferable to the otherwise Herculean efforts that would be needed to cool peripheral logic 104 and processor core 106 layer(s) having the plurality of memory layers 102 between it and the cooling solution 108 (FIG. 1).

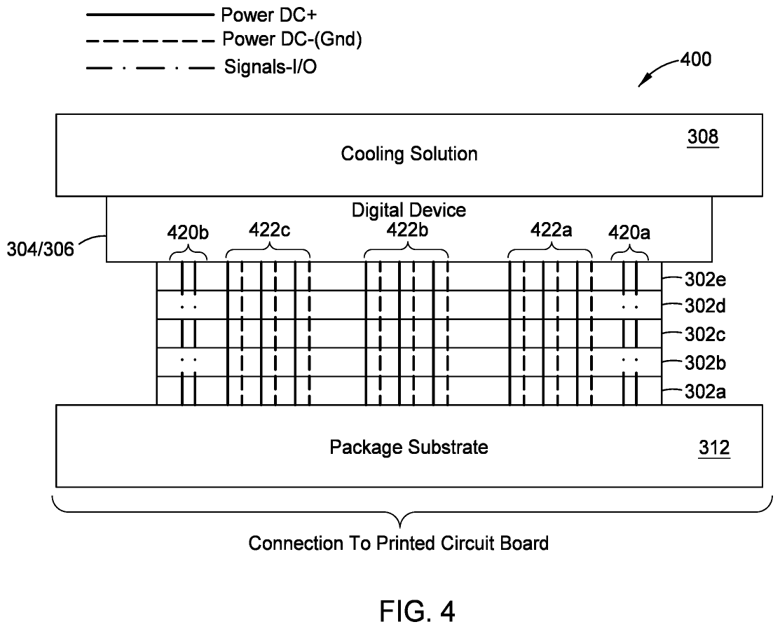

Referring to FIG. 4, depicted is a representative schematic elevational cross-section layout of a three-dimensional digital device/memory stack showing power, ground and signal connections between a digital device layer and a package substrate with a plurality of memory layers there between, according to an example. A three-dimensional digital device/memory stack, generally represented by the numeral 400, comprises a digital device layer(s) 304, a plurality of integrated circuit (IC) semiconductor memory (die) layers 302 vertically stacked one below another and located between the digital device layer(s) 304 and a package substrate 312. The digital device layer(s) 304 are closest to a cooling solution 308 for optimal cooling thereof. A plurality of TSVs 422 for DC+ power and DC-ground may deliver the power required by the circuits of the digital device layer(s) 304 and the plurality of memory layers 302. TSVs 420, as needed, may be provided for all input-output (I/O), control and testing signal requirements. TSVs 420, 422 represent the I/O-control, and power connections between the package substrate 312 and the circuits of the digital device layer(s) 304. The digital device layer(s) 304 may also provide power and I/O signals to the plurality of memory layers 302.

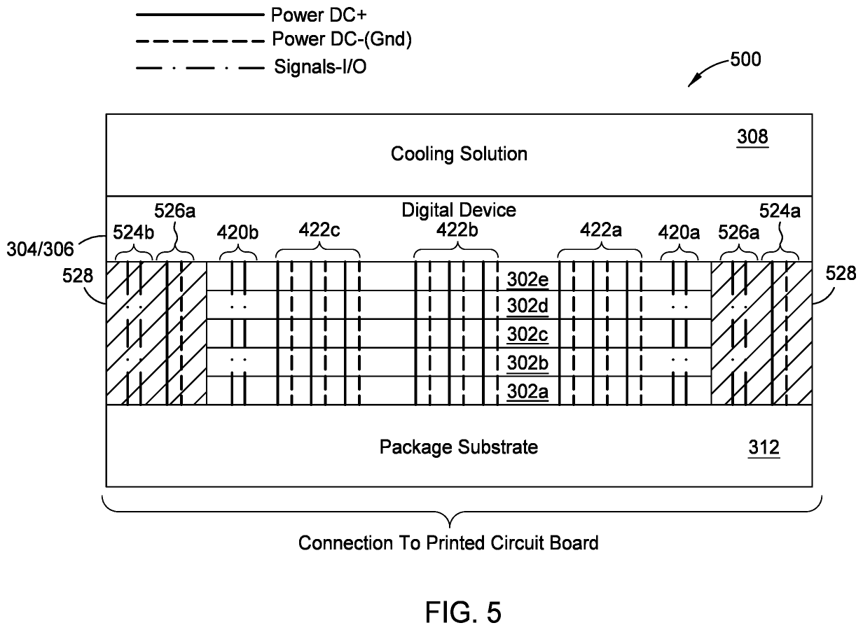

Referring to FIG. 5, depicted is a representative schematic elevational cross-section layout of a three-dimensional digital device/memory stack showing through-mold/through-dielectric vias (TDVs) directly between the digital device and the package substrate, according to an example. A three-dimensional digital device/memory stack, generally represented by the numeral 500, is substantially the digital device/memory stack 400 of FIG. 4, with the addition of through-mold/through-dielectric vias (TDVs) 524, 526 directly between the digital device layer(s) 304 and the package substrate 312; circumventing the plurality of memory layers 302. These TDVs 524, 526 can potentially be larger (in diameter) than the TSVs 420, 422 and thereby have lower resistance and higher current-carrying capabilities, both of which may be beneficial for either power delivery (to reduce, for example but not limited to, IR drop, better electro-migration characteristics) or for the signal integrity of I/O signals (lower resistance-capacitance (RC) of TDVs 524). The TDVs 524 may be used for signal I/O and the TDVs 526 may be used for power and power common (ground). The TDVs 524, 526 may be encased in mold material 528 and whose size and number are restricted only by the area/volume available between the digital device layer(s) 304 and the package substrate 312.

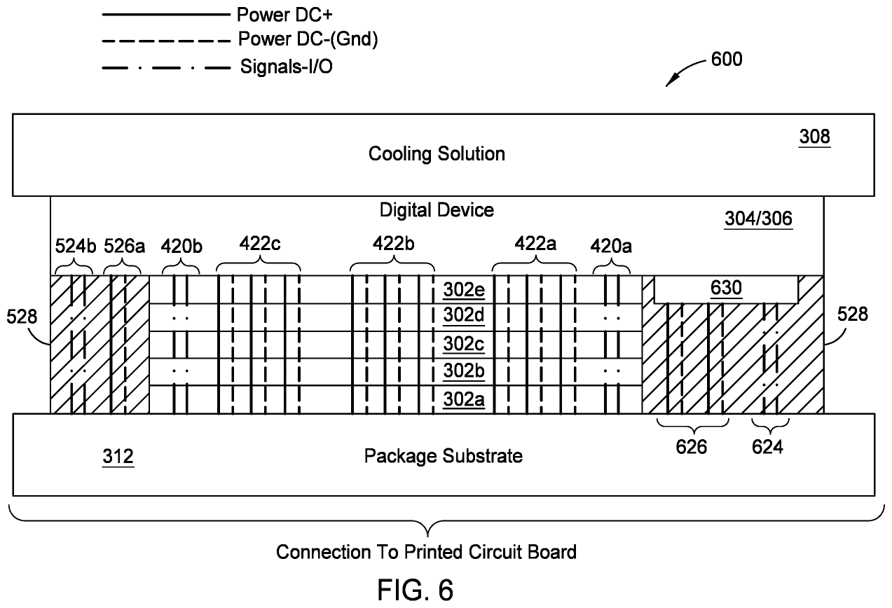

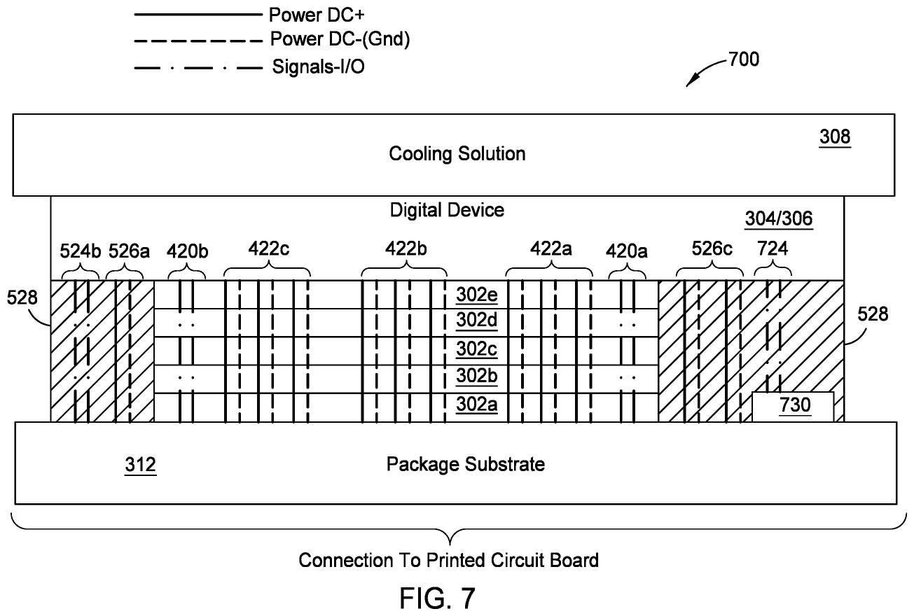

Referring to FIGS. 6 and 7, depicted are representative schematic elevational cross-section layouts of three-dimensional memory stacks having at least one non-memory silicon die alongside the memory stack that provides connectivity directly between the digital device and the package substrate, according to examples. In one example, a three-dimensional digital device/memory stack, generally represented by the numeral 600 (FIG. 6), may comprise a passive silicon die 630 including only electrical connections from the digital device layer(s) 304 to the package substrate 312. These electrical connections may be coupled to TDVs 626 for DC power and ground and TDVs 624 for input-output (I/O) signals.

In another example, a three-dimensional memory stack, generally represented by the numeral 700 (FIG. 7), may comprise an active silicon die 730 having, for example but not limited to, input-output drivers and associated logic. TDVs 724 may connect from the digital device layer(s) 304 to circuitry in the active silicon die 730, which may then connect to the package substrate 312 for directly driving package-level signals. This may be advantageous because it allows more sensitive analog I/O circuitry to directly interface with the package substrate, as opposed to the I/O drivers shown in FIG. 6 which must contend with the additional resistor-capacitor (RC) time delay introduced by the TDVs 624 to access the package interface 312.

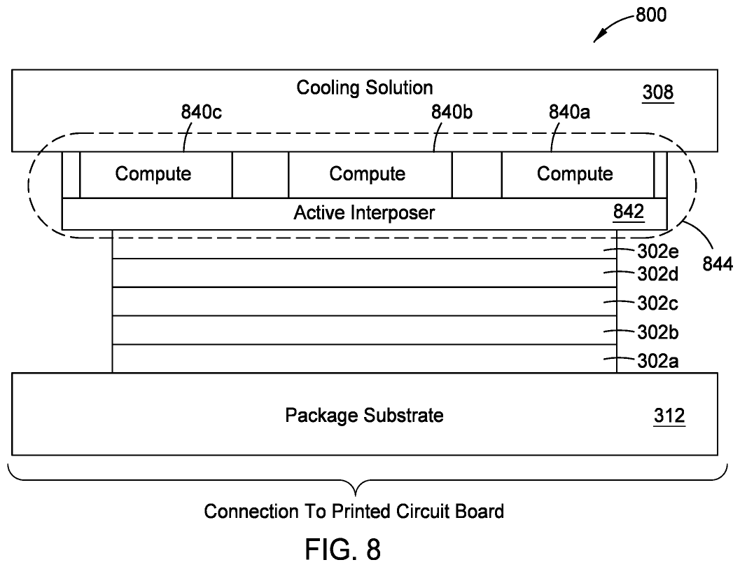

Referring to FIG. 8, depicted is a representative schematic elevational cross-section layout of a three-dimensional digital device/memory stack showing a plurality of compute modules and an active interposer layer between a cooling solution and a plurality of memory layers, according to an example. The logic portion may consist of a more complex module comprising a plurality of logic devices integrated together to form a compound semiconductor module. A three-dimensional digital device/memory stack, generally represented by the numeral 800, may comprise a plurality of compute modules (chiplets) 840, an active interposer layer 842 coupled to the plurality of compute modules 840, a plurality of memory layers 302, and a package substrate 312. The plurality of compute modules 840 are proximate (closest) to a cooling solution 308 for optimal cooling thereof. The plurality of compute modules 840 and the active interposer layer 842 make up a compound semiconductor module 844. The active interposer layer 842 is also electrically coupled to the plurality of memory layers 302. Electrical connections between the active interposer 842 and a package substrate 312 can be made through TSVs and TDVs, as shown and disclosed hereinabove. A compute module 840 may be, for example but is not limited to, a microcontroller, a microprocessor, a mixed signal processor, a central processing unit (CPU), a programmable logic array (PLA), an application specific integrated circuit (ASIC), a digital signal processor (DSP), a graphics processing unit (GPU), a field programmable gate array (FPGA), neural processing unit, tensor processing unit, and the like.

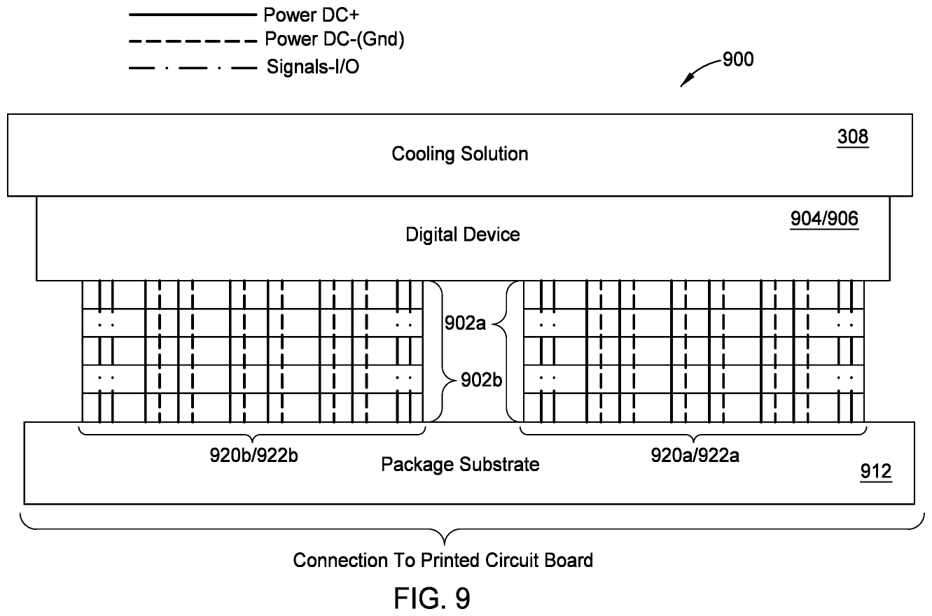

Referring to FIG. 9, depicted is a representative schematic elevational cross-section layout of a three-dimensional digital device/memory stack having a digital device layer interposed between a cooling solution and multiple stacks of pluralities of memory layers, according to an example. A three-dimensional digital device/memory stack, generally represented by the numeral 900, comprises a digital device layer(s) 304, and at least two memory stacks 902a, 902b. Each memory stack 902a, 902b comprises a plurality of memory layers 302 vertically stacked one below another with the digital device layer(s) 304 proximate (closest) to a cooling solution 308. The digital device layer(s) 304 is electrically coupled to the at least two memory stacks 902a, 902b. Electrical connections between the digital device layer(s) 304 and a package substrate 912 can be made through TSVs 920/922, as shown and disclosed hereinabove.

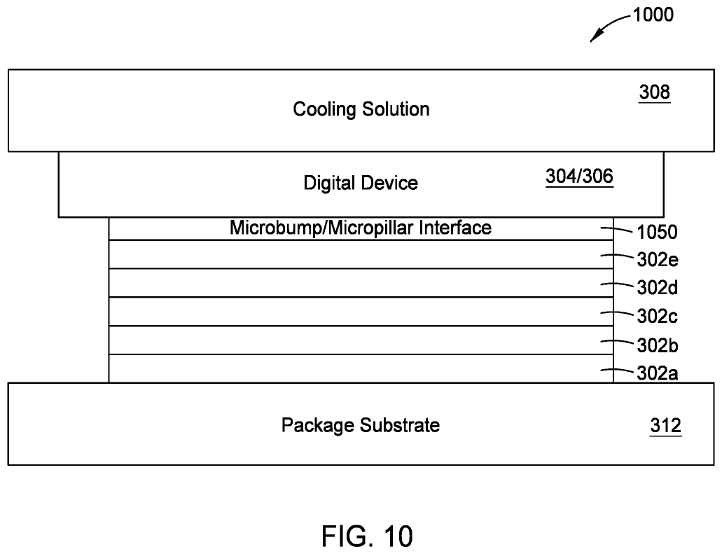

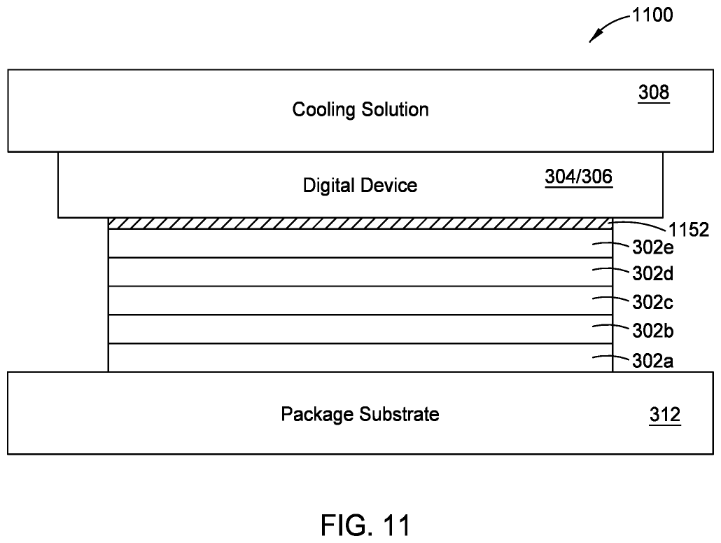

Referring to FIGS. 10 and 11, depicted are representative schematic elevational cross-section layouts of three-dimensional digital device/memory stacks using different types of electrical bonding technologies, according to examples. As shown in FIG. 10, a three-dimensional digital device/memory stack, generally represented by the numeral 1000, may utilize microbump or copper micropillar technology to electrically interconnect a digital device layer(s) 304 to a plurality of memory layers 302 with a microbump/micropillar interface 1050 there between. As shown in FIG. 11, a three-dimensional digital device/memory stack, generally represented by the numeral 1100, may comprise a hybrid-bond interface 1152, using hybrid bonding technology, to electrically interconnect the digital device layer(s) 304 to the plurality of memory layers 302.

While the microbump/micropillar interface 1050 may pose a higher resistance than using hybrid bonding, the digital device/memory stack 1000 may only use the microbumps at the singular memory-to-logic interface (but may continue to utilize hybrid bonding within the memory stack itself), which is far more manageable in terms of resistance/IR-drop concerns. Contrast this to the prior art approach shown in FIG. 1 (Agarwal et al.), where microbumps are used between every layer of the memory stack 100 (which with modern DRAM stacks already eight layers deep would be a far more challenging voltage drop (IR) situation to deal with).

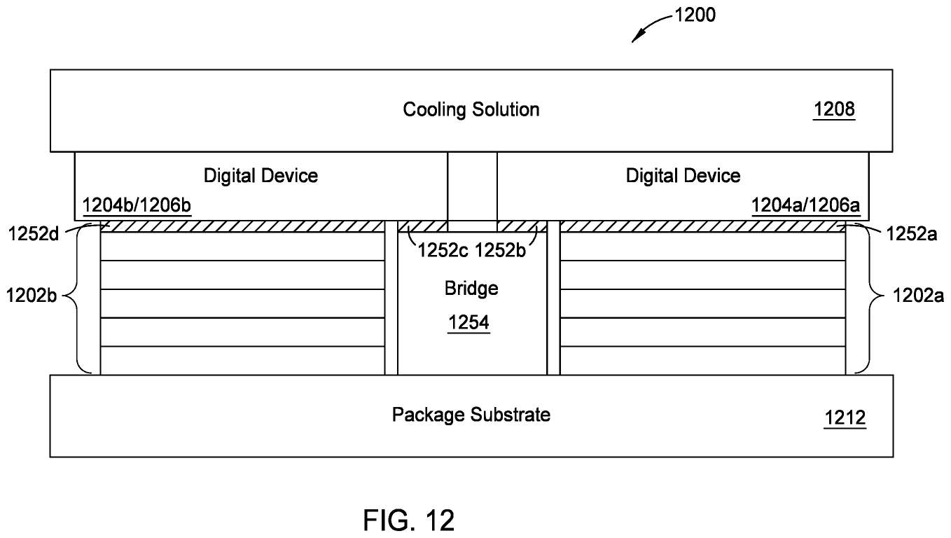

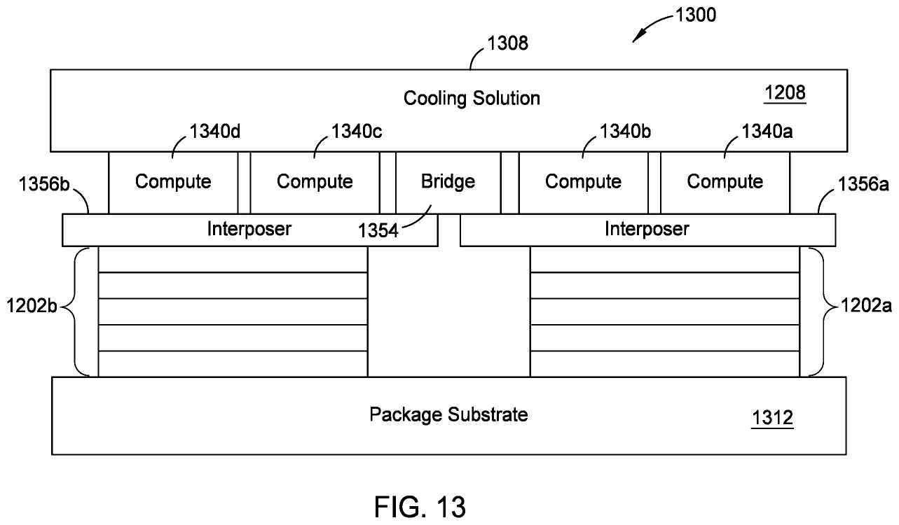

The examples shown in FIGS. 3-11 and the descriptions thereof disclosed herein may include multiple digital device modules connected through various silicon bridge technologies. Referring to FIGS. 12 and 13, depicted are representative schematic elevational cross-section layouts of three-dimensional digital device/memory stacks having at least two digital device modules connected through various silicon bridge technologies to at least two memory stacks.

FIG. 12 shows a three-dimensional digital device/memory stack, generally represented by the numeral 1200, may comprise a first digital device layer 1204a/1206a and a second digital device layer 1204b/1206b in close thermal proximity to a cooling solution 1208. The first digital device layer 1204a/1206a is electrically coupled to a first memory stack 1202a with an interface 1252a, using any of the aforementioned connection technologies. The second digital device layer 1204b/1206b is electrically coupled to a second memory stack 1202b with an interface 1252d, using any of the aforementioned connection technologies. A silicon bridge 1254 may be used to provide electrical coupling between the first digital device layer 1204a/1206a and the second digital device layer 1204b/1206b using interface layers 1252b and 1252c there between. Microbumps/micropillar technology may be used for connections to the interface layers 1252. Connections of the package substrate 1212 may be made to the first digital device layer 1204a/1206a and the second digital device layer 1204b/1206b using TSVs and/or TDVs (not shown) as disclosed hereinabove.

FIG. 13 shows a three-dimensional digital device/memory stack, generally represented by the numeral 1300, that may comprise a plurality of compute modules 1340, at least two interposers 1356, a bridge 1354, at least two memory stacks 1202, and a package substrate 1312. The plurality of compute modules 1340 are in close thermal proximity to a cooling solution 1308. Some of the plurality of compute modules 1340a and 1340b are electrically coupled to a first memory stack 1202a with a first interposer 1356a, and some other of the plurality of compute modules 1340c and 1340d are electrically coupled to a second memory stack 1202b with a second interposer 1356b. The interposers 1356 may be active or passive. A silicon bridge 1354 may be used to provide electrical coupling between the first and second active interposers 1356a, 1356b. Interconnections between the plurality of compute modules1340, the at least two active interposers 1356, the bridge 1354, the at least two memory stacks 1202 and the package substrate 1312 may be made with a compound construct utilizing hybrid-bonding technologies, e.g., hybrid-bonded small outline integrated circuit (SOIC)-L bridge and the like. Connections to the package substrate 1312 from individual layers may be made to the at least two active interposers 1356 and the memory layers of the at least two memory stacks 1202 using TSVs and/or TDVs (not shown) as disclosed hereinabove. It is contemplated and within the scope of this disclosure that the interposers 1356 may be active or passive.

Placement of the digital device/compute module on top of an active interposer on top of a memory stack also provides a more natural data flow from cache-miss (core chiplet) to data fabric and memory controller (active interposer) to the memory. It is contemplated and within the scope of this disclosure that the semiconductor memory may consist of one or more memory technologies including but not limited to DRAM, SRAM, PCM, FeRAM, STT-MRAM, eDRAM, and the like. One or more memory layers may include additional functionality, such as compute or processing (e.g., processing in memory or PIM). Also, the use/need for TSVs through the most expensive logic/compute chiplets is avoided.

As will be appreciated by one skilled in the art and having the benefit of this disclosure, the embodiments disclosed herein may be embodied as a system, method, apparatus, or computer programmed product. Accordingly, aspects may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects may take the form of a computer program product embodied in one or more computer readable medium(s) having computer readable program code embodied thereon.

While the foregoing is directed to embodiments of the present invention, other and further embodiments of the invention may be devised without departing from the basic scope thereof, and the scope thereof is determined by the claims that follow.

What is claimed:

1. An integrated circuit (IC) die stack, comprising:
a digital device layer having a memory interface;
a cooling solution on a first side of the digital device layer; and
a plurality of memory layers on a second side of the digital device layer opposite the first side thereof.

2. The IC die stack according to claim 1, further comprising a package substrate attached to an opposite side of the plurality of memory layers attached to the digital device layer.

3. The IC die stack according to claim 1, wherein the digital device layer and the plurality of memory layers are electrically interconnected.

4. The IC die stack according to claim 2, wherein the digital device layer and the plurality of memory layers are electrically interconnected with through-silicon vias (TSVs).

5. The IC die stack according to claim 4, wherein the TSVs are adapted for coupling to external connections on the package substrate.

6. The IC die stack according to claim 5, wherein the external connections are adapted for coupling to power, ground, and input-output and control signals.

7. The IC die stack according to claim 1, wherein the digital device layer is selected from the group consisting of any one or a combination of a microcontroller, a microprocessor, a mixed signal processor, a central processing unit (CPU), a programmable logic array (PLA), an application specific integrated circuit (ASIC), a digital signal processor (DSP), a graphics processing unit (GPU), a field programmable gate array (FPGA), neural processing unit and tensor processing unit.

8. The IC die stack according to claim 1, wherein the plurality of memory layers are selected from the group consisting of dynamic random-access memory (DRAM), static random-access memory (SRAM), serial shift registers, eDRAM, Flash, phase-change memory, resistive RAM, ferromagnetic RAM and spin-torque transfer RAM.

9. The IC die stack according to claim 1, wherein the cooling solution is a thermal dissipation device with heat transfer enhancement structures selected from the group consisting of a heat sink, a heat sink with fins, liquid cooling tubes, vapor chambers, heat pipes, and cold plates.

10. The IC die stack according to claim 2, further comprising through-mold/through-dielectric vias (TDVs) adapted for coupling power, ground, and input-out and control signals directly between the digital device layer and the package substrate.

11. The IC die stack according to claim 10, further comprising a passive silicon die coupled directly to the digital device layer and to the package substrate through TDVs.

12. The IC die stack according to claim 10, further comprising an active silicon die coupled directly to the package substrate and to the digital device layer through TDVs.

13. The IC die stack according to claim 1, wherein the digital device layer comprises a plurality of compute modules, wherein at least one of the plurality of compute modules has a memory interface.

14. The IC die stack according to claim 13, further comprising an active interposer layer between the plurality of compute modules and the plurality of memory layers.

15. The IC die stack according to claim 1, further comprising a logic layer electrically coupled to the digital device layer.

16. The IC die stack according to claim 1, wherein metal pads between the plurality of memory layers are coupled together using hybrid-bonding.

17. An integrated circuit (IC) die stack, comprising:
a first digital device layer having at least two memory interfaces;
a cooling solution on a first side of the first digital device layer;
at least two memory stacks, each comprising a plurality of memory layers on a second side of the first digital device layer opposite the first side thereof;
an interface layer between the first digital device layer and the at least two memory stacks; and
a package substrate coupled to the at least two memory stacks on the opposite side of the at least two memory stacks coupled to the first digital device layer.

18. The IC die stack according to claim 17, further comprising a second digital device layer and a bridge coupling the first and second digital device layers through the interface layer.

19. An integrated circuit (IC) die stack, comprising:
a plurality of compute modules, wherein at least one of the plurality of compute modules has a memory interface;
a cooling solution on a first side of the plurality of compute modules;
at least two memory stacks, each comprising a plurality of memory layers on a second side of the plurality of compute modules opposite the first side thereof;
interposer layers between the plurality of compute modules and the at least two memory stacks;
a bridge electrically intercoupling the interposer layers; and
a package substrate coupled to the at least two memory stacks on the opposite side of the at least two memory stacks coupled to the interposer layers.

20. The IC die stack according to claim 19, wherein the interposer layers comprise active logic.
